(19) United States
(12) Patent Application Publication
(10) Pub. No.: US 2016/0260794 A1
(43) Pub. Date: Sep. 8, 2016

(54) COIL INDUCTOR

(71) Applicant: GLOBALFOUNDRIES Inc., Grand Cayman (KY)

(72) Inventors: Oliver Aubel, Dresden (DE); Frank Feustel, Dresden (DE); Thomas Werner, Reichenberg-Moritzburg (DE)

(21) Appl. No.: 14/634,978

(22) Filed: Mar. 2, 2015

(51) Int. Cl. H01L 49/02

(52) U.S. Cl. CPC H01L 28/10

(57) ABSTRACT

A method of forming a semiconductor device including an inductor is provided, including forming a first dielectric layer of a first dielectric material over a substrate, removing part of the first dielectric layer to create an opening in the first dielectric layer, filling the opening with a second dielectric layer of a second dielectric material different from the first dielectric material, forming a trench in the second dielectric layer, and filling the trench with a conductive material to form an inductor coil. A semiconductor device is provided that includes a first dielectric layer made of a first dielectric material, a second dielectric layer made of a second dielectric material different from the first dielectric material and embedded in the first dielectric layer and a trench filled with a conductive material and formed in the second dielectric layer, representing at least a part of an inductor coil of the inductor.

### BACKGROUND OF THE INVENTION

1. Field of the Invention

Generally, the present disclosure relates to the field of integrated circuits and semiconductor devices and, more particularly, to the formation of high quality coil inductors used in integrated circuits.

2. Description of the Related Art

The fabrication of advanced integrated circuits, such as CPUs, storage devices, ASICs (application specific integrated circuits) and the like, requires the formation of a large number of circuit elements on a given chip area according to a specified circuit layout. More recently, with the advent of integrated circuits and electronic miniaturization, the need arose to reduce the size of external discrete components necessary with an integrated circuit product, preferably, elimination of any discrete components was a primary goal. More and more, formerly discrete components were fabricated onto integrated circuits, i.e., resistors, capacitors and inductors, for both size and cost reasons. Inductors ere especially a problem because of the physical size and geometry normally required for an effective inductor over a desired range of frequencies. In general, inductors are important components in many of the building blocks in wireless communication systems, such as RF bandpass filters, oscillators, impedance matching networks and/or emitter degeneration circuits. Wireless communication standards place stringent requirements on performance and operating parameters, such as noise interference/immunity and power consumption. To accommodate the stringent requirements, high quality (Q) inductors are needed.

Ideally, an inductor acts as a purely reactive device. However, in reality, the performance of an inductor is impacted by parasitic losses distributed within the inductor. The real inductor incurs losses that are due to, for example, built-in resistance of the wire. Other losses may also include those due to, for example, skin effect, proximity effect, as well as eddy current in the underlying substrate. The losses incurred by the inductor are represented as Rₛ or effective series resistance. The total impedance Z of the circuit is defined as Z=Rₛ+X_{L} including real component Rₛ, and an imaginary component X_{L} which is the effective reactance. The effective reactance of the inductor X_{L} is equal to jωL. As such the total impedance Z of the inductor is defined as Z=Rs+jωL. The Q factor indicates how close a real inductor is to an ideal inductor. The higher the Q factor, the better is the performance of the inductor. The Q factor is defined by Q=Im(Z)/Re(Z)=ωL/Rₛ. Typically, a high Q factor is associated with a low signal loss. Despite the recent engineering progress, there is still a need for methods of manufacturing inductors with increased Q values.

The switch-on and switch-off characteristics of the current in an LR series circuit is given by

$${I}_{L} ( t ) = \frac{{U}_{0}}{{R}_{s}} ( 1 - {e}^{- \frac{{tR}_{L}}{L}} ) and {I}_{L} ( t ) = \frac{{U}_{0}}{{R}_{s}} {e}^{- \frac{{tR}_{L}}{L}} ,$$

respectively, where RL denotes the line resistivity.

Thus, the inductor coil quality is affected by the resistivity of the involved metal lines, typically, Cu lines. It should be noted that the coil quality depends on the resistance of the coil trenches (conductor lines filled in trenches formed in a dielectric material) as well as the number of coil windings (coil density) but not on the k-value of the dielectric wherein the coil is formed.

An inductor fabricated on an integrated circuit substrate generally has been formed in the shape of a spiral coil structure in a single metal layer on an insulation layer using typical integrated circuit fabrication techniques. This spiral coil structure requires a substantial area of the silicon integrated circuit substrate, typically, for example, 200 μm×200 μm. The conventional spiral coil structure also suffers from parasitic capacitive influence from the integrated circuit substrate on which it is fabricated.

Thus, there is particularly a need for the formation of a high Q inductor with reduced spatial dimensions as compared to conventionally Back-End-of-Line (BEOL) manufactured inductors.

In view of the situation described above, the present disclosure provides techniques that allow for the formation of space-saving inductors with high Q values.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

An illustrative method of the formation of a semiconductor device with an inductor includes the steps of forming a first dielectric layer of a first dielectric material over a substrate, removing a part of the first dielectric layer to create an opening in the first dielectric layer, filling the opening with a second dielectric layer of a second dielectric material different from the first dielectric material, forming a trench in the second dielectric layer and filling the trench with a conductive material to form an inductor coil. Herein, by the term “conductive,” it is meant “electrically conductive.” The first dielectric layer may be formed as part of, or on, or over a metallization layer formed over the substrate. The first dielectric layer may be formed on or over a device layer that includes a variety of semiconductor devices, for example, transistor devices and/or resistors and/or capacitors. The device layer may be formed over the substrate or on and partially in the substrate. The formed opening may reach to an underlying metallization layer or device layer. The second dielectric material may be chosen to allow for the formation of deep trenches with small critical dimensions, in particular, smaller than the critical dimensions of trenches used for the formation of inductor coils of the art.

It is further provided a semiconductor device including an inductor, wherein the semiconductor device comprises a first dielectric layer made of a first dielectric material, a second dielectric layer made of a second dielectric material different from the first dielectric material and embedded in the first dielectric layer and a trench filled with a conductive material and formed in the second dielectric layer and representing at least a part of an inductor coil of the inductor.

Furthermore, it is provided a method of forming a semiconductor device including an inductor, including the steps of forming a dielectric layer over or as part of a metallization layer or over a device layer and performing a two-step etching process of the dielectric layer. The two-step etching process includes a first etching step to form a first trench with a first depth in the dielectric layer and a second etching step to form a second trench with a second depth in the dielectric layer and to further etch the first trench to increase the depth of the first trench to a third depth deeper than the second depth. During the second etching step, the second trench is formed and simultaneously the depth of the first trench is increased in one single processing step. After the first trench with the third depth has been formed, a process of filling the first trench with the third depth with a conductive material to form an inductor coil is performed. For example, the conductive material may consist of or comprise copper.

All or some of the above-mentioned dielectric layers may be formed of a low-k material, with a dielectric constant k less than 3, for example.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1c illustrate a method of the formation of a semiconductor device comprising an inductor comprising a two-step trench etching process according to an example of the present invention;

FIG. 2 illustrates a semiconductor device comprising a coil inductor that may be formed according to the method illustrated in FIGS. 1a-1c;

FIG. 3 illustrates a semiconductor device comprising a three-dimensional coil inductor formed of coil turns at different layer levels of the semiconductor device; and

FIGS. 4a-4d illustrate a method of the formation of a semiconductor device comprising a coil inductor comprising replacement of a dielectric according to another example of the present invention.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The following embodiments are described in sufficient detail to enable those skilled in the art to make use of the invention. It is to be understood that other embodiments would be evident, based on the present disclosure, and that system, structure, process or mechanical changes may be made without departing from the scope of the present disclosure. In the following description, numeral-specific details are given to provide a thorough understanding of the disclosure. However, it will be apparent that the embodiments of the disclosure may be practiced without the specific details. In order to avoid obscuring the present disclosure, some well-known circuits, system configurations, structure configurations and process steps are not disclosed in detail.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

The present disclosure provides methods for forming an inductor, in particular, a coil inductor. As will be readily apparent to those skilled in the art upon a complete reading of the present application, the present method is applicable to a variety of technologies, for example, NMOS, PMOS, CMOS, etc., and is readily applicable to a variety of devices, including, but not limited to, logic devices, memory devices, etc., in principle. The techniques and technologies described herein can be utilized to fabricate MOS integrated circuit devices, including NMOS integrated circuit devices, PMOS integrated circuit devices, and CMOS integrated circuit vices. Although the term “MOS” properly refers to a device having a metal gate electrode and an oxide gate insulator, that term is used throughout to refer to any semiconductor device that includes a conductive gate electrode (whether metal or other conductive material) that is positioned over a gate insulator (whether oxide or other insulator) which, in turn, is positioned over a semiconductor substrate. It should be stressed that according to the method of manufacturing a semiconductor device that is described herein, the formation of an inductor, may be integrated within the process flow of manufacturing a plurality of active devices on a wafer, including transistor devices. Exemplary embodiments will now be described with reference to the drawings.

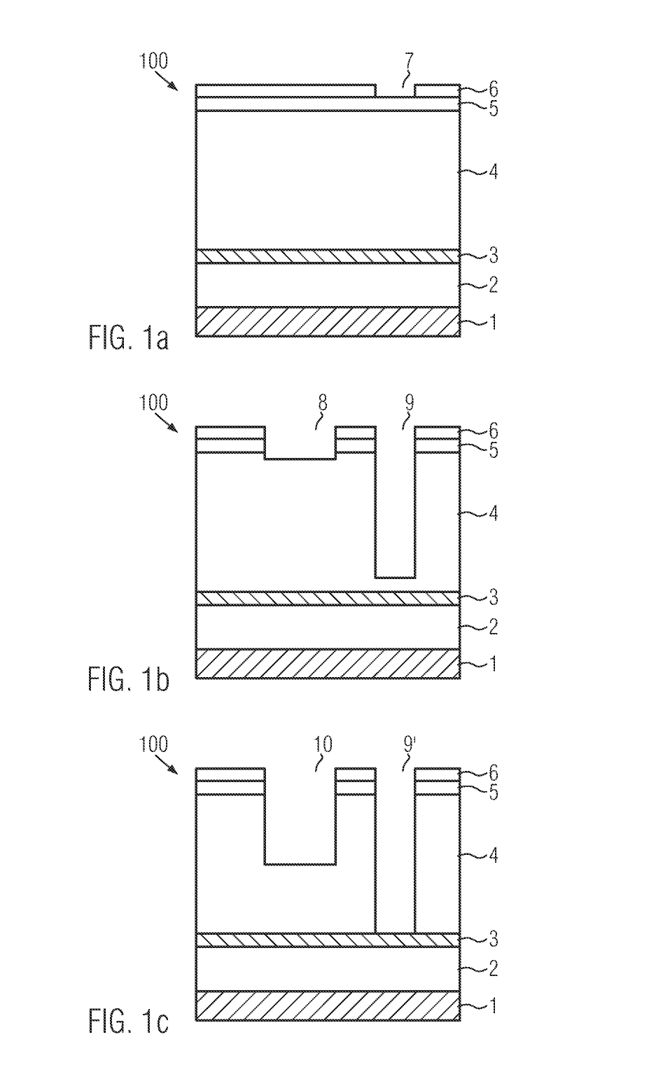

FIG. 1a schematically illustrates a cross-sectional view of a semiconductor device 100 during a manufacturing stage. The semiconductor device 100 comprises a substrate 1, which may represent any substrate that is appropriate for the formation of circuit elements thereon. For instance, the substrate 1 may be a bulk semiconductor substrate, an insulating substrate having formed thereon a semiconductor layer, such as a crystalline silicon region, a silicon/germanium region, or any other III-V semiconductor compound, or II-VI compound, and the like. The substrate 1 may include a semiconductor-on-insulator (SOI) substrate including a layer of a semiconductor material, for example a silicon layer, that is formed above a support substrate, which may be a silicon wafer, and is separated therefrom by a layer of an electrically insulating material, for example a silicon dioxide layer. The substrate 1 may comprise a semiconductor layer, which in turn may be comprised of any appropriate semiconductor material, such as silicon, silicon/germanium, silicon/carbon, other II-VI or III-V semiconductor compounds and the like. Typically, the substrate 1 may represent a carrier having formed thereon a large number of circuit elements, such as transistors, capacitors and the like, as are required for advanced integrated circuits (not shown in FIG. 1a). These circuit elements may be electrically connected in accordance with a specific circuit design by means of one or more metallization layers, in principle. The substrate may be a Fully Depleted SOI substrate wherein Fully Depleted SOI FETs are formed.

The semiconductor device 100 may comprise a dielectric 2, which may be formed over a metallization layer or represent the dielectric material of a metallization layer (“wiring layer”), or may be any interlayer dielectric (ILD) material and the like. In highly advanced semiconductor devices, the dielectric layer 2 may comprise a low-k dielectric material so as to reduce the parasitic capacitance between neighboring metal lines. In this respect, a low-k dielectric material is to be understood as a dielectric having a relative permittivity (dielectric constant k) that is less than approximately 3.0 and hence exhibits a significantly smaller permittivity than, for instance, well-established “conventional” dielectrics, such as silicon dioxide, silicon nitride and the like. After any well-established process techniques for forming any circuit elements and microstructural elements in and on the substrate 1, the dielectric layer 2 may be formed, which may comprise two or more s layers, depending on device requirements. For example, the dielectric layer 2 may be formed on the basis of well-established plasma enhanced chemical vapor deposition (PECVD) techniques, when comprising silicon dioxide, silicon nitride and the like. However, other deposition techniques may be used, such as spin-on techniques for any low-k polymer materials and the like.

Another layer 3 is formed over the dielectric layer 2. The layer 3 may be a device layer comprising active and/or passive semiconductor devices formed on a substrate or a metallization layer. The layer 3 may be a metallization layer. Above this layer 3, another dielectric layer 4 is formed that may be an (interlayer dielectric) ILD layer. The dielectric layer 4 may also be formed of a low-k material. A planarization process, for example, a chemical mechanical polishing process, may be performed after the deposition of the dielectric layer 4 for obtaining a substantially planar surface. In the chemical mechanical polishing process, the surface of the semiconductor structure 100 is moved relative to a polishing pad while a slurry is supplied to an interface between the surface of the semiconductor structure 100 and the polishing pad. The slurry can react chemically with portions of the semiconductor structure 100 at the surface, and reaction products may be removed by friction between the semiconductor structure 100 and the polishing pad and/or by abrasion caused by abrasive particles in the slurry.

Above the dielectric layer 4, a first mask layer 5 and a second mask layer 6 are formed. The first and second mask layers 5 and 6 may be formed as hard masks. Suitable materials include metals and SiN, for example. The second mask layer 6 may be formed of a material different from the one of the first mask layer 5. The second mask layer 6 is patterned to expose the first mask layer 5 in a first open region (see FIG. 1a).

A first trench 9 is formed, for example, by anisotropic etching, in the dielectric layer 4 through the first opening 7 of the patterned second mask layer 6, as is shown in FIG. 1b. For instance, well-known etching recipes include fluorine and carbon or fluorine, carbon and hydrogen compounds. After formation of the trench 9, the first and second mask layers 5 and 6 are patterned to expose the dielectric layer 4 in a second opening 8. Some material of the dielectric layer 4 may be removed during the patterning process. As shown in FIG. 1c, another etching process is performed using the patterned first and second mask layers 5 and 6 comprising openings 7 and M. The second etching process results in the formation of a second trench 10 in the dielectric layer 4 and deepening the trench 9 to obtain a trench 9′ that might reach down to the device or metallization layer 3. For example, trench 9′ wherein the inductor is to be formed may have a depth corresponding to a depth of a “normal” trench 10 plus a via height of a via formed in the dielectric layer 4. As compared to the art, the inductor trench has a larger depth. An inductor of the art has a trench depth corresponding to the depth of “normal” trench 10.

In order to form an inductor, the trench 9′ is filled with some conductive material, for example, copper. Filling the trench 9′ may comprise forming a barrier layer that may be formed by any appropriate deposition technique, such as sputter deposition, chemical vapor deposition, atomic layer deposition and the like. For instance, the barrier layer may be comprised of conductive materials, such as tantalum, tantalum nitride, titanium, titanium nitride, tungsten, tungsten nitride or any other appropriate material, wherein, in some embodiments, two or more different material compositions and layers may be provided, as is required for achieving the desired adhesion and diffusion blocking characteristics. For example, the barrier layer may be deposited on the basis of an electrochemical deposition process so as to form a conductive capping layer in the trench 9′, wherein an appropriate catalyst material may be deposited prior to the actual formation of the harder layer. For instance, palladium may act as a catalyst material for initiating the deposition of the conductive capping layer in an electroless plating process, wherein, after an initial deposition of the material, such as COWP, the subsequent deposition process is auto catalyzed by the previously deposited material.

After the deposition of the barrier layer, a copper seed layer may be deposited by any appropriate deposition technique, such as sputter deposition, electroless deposition and the like, if a copper-based material is to be filled in on the basis of well-established electroplating techniques. In other embodiments, the provision of a seed layer may not be required. Thereafter, a metal material, for example in the form of a copper-containing metal, may be deposited in the trench 9′ on the basis of well-established techniques, such as electroplating, electroless plating and the like.

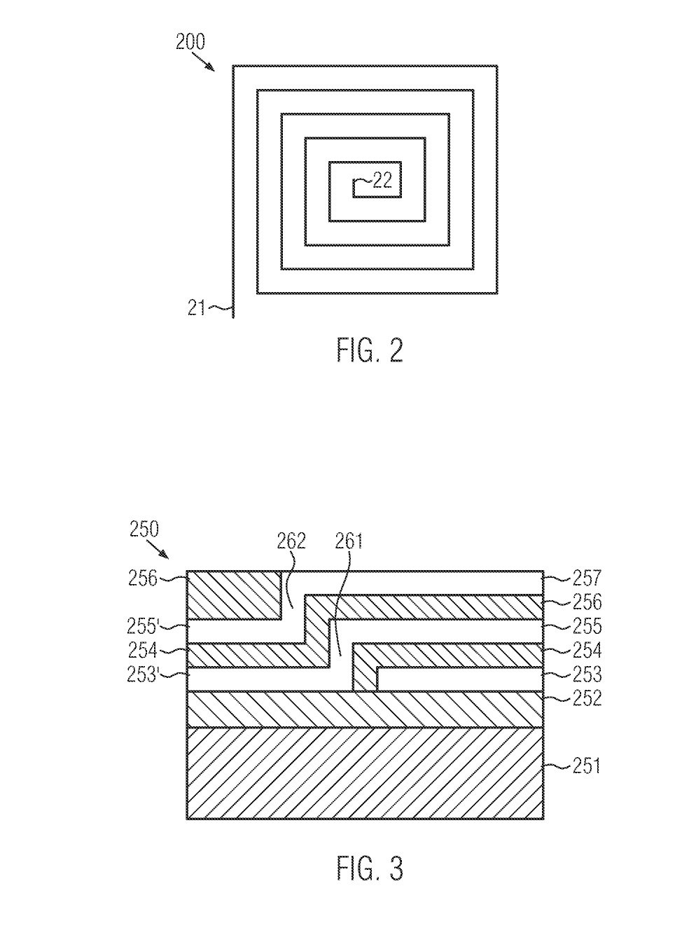

By the process described with reference to FIGS. 1a-1c, a spirally wound inductor coil 200 may be formed over an IC substrate, as shown in FIG. 2. FIG. 2 may represent a top view of the cross-sectional view of FIG. 1c after the trench 9′ has been filled with a conductive material, for example, copper. The resulting inductor coil has a first end 21 and a second end 22. In the center of the coil, a core may be formed. Both the coil windings and the core are formed in the dielectric layer 4 shown in FIGS. 1a-1c. The “normal” trench 10 shown in FIG. 1c may also be filled with a conductive material comprising a barrier layer and a metal, which, in particular embodiments, may be a copper-containing metal, for example.

By the method described with reference to FIGS. 1a-1c and 2, a low-resistance coil inductor may be formed. As compared to the art, the employment of deeper trenches results in a lower coil resistance and, therefore, better coil quality, i.e., a higher Q value, and improved inductor performance.

The coil inductor shown in FIG. 2 has multiple windings and segments. In the example described with reference to FIGS. 1a-1c, the windings/segments (coil turns) are formed on the same level of semiconductor device 100 in the dielectric layer 4. However, different windings/segments might be formed at different levels. For example, the inductor may comprise windings/segments formed both in dielectric layers 2 and 4. The windings/segments formed at different levels might be connected by vias filled with a conductive material wherein the vias extend from one dielectric layer to another (for example, from dielectric layer 2 through metallization layer 3 to dielectric layer 4). The trenches for the windings/segments in each dielectric layer may be formed in accordance with the two-step etching process described with reference to FIGS. 1a-1c.

FIG. 3 shows an example of a semiconductor device 250 comprising a three-dimensional inductor coil formed at different levels of the semiconductor device 250. The semiconductor device 250 comprises a substrate 251. A dielectric layer 252 is formed over the semiconductor device 250. Segments 253 and 253′ of an inductor coil are formed over the dielectric layer 252. Similarly, segments 255 and 255′ of the inductor coil are formed over a dielectric layer 254 and segment 257 of the inductor coil is formed over and partially in a dielectric layer 256. All of the segments (coil turns) 253, 253′, 255, 255′ and 257 might be formed in accordance with the two-step trench etching process described with reference to FIGS. 1a-1c. Alternatively, only segments of a particular level, say, segments 255 and 255′, might be formed in accordance with the two-step trench etching process described with reference to FIGS. 1a-1c.

Segments of different levels may be connected to each other by means of electrical connections or vias 261 and 262 formed in the dielectric materials. The coil inductor shown in FIG. 3 may be mainly formed in ILD layers or dielectric layers of or formed over metallization layers, for example.

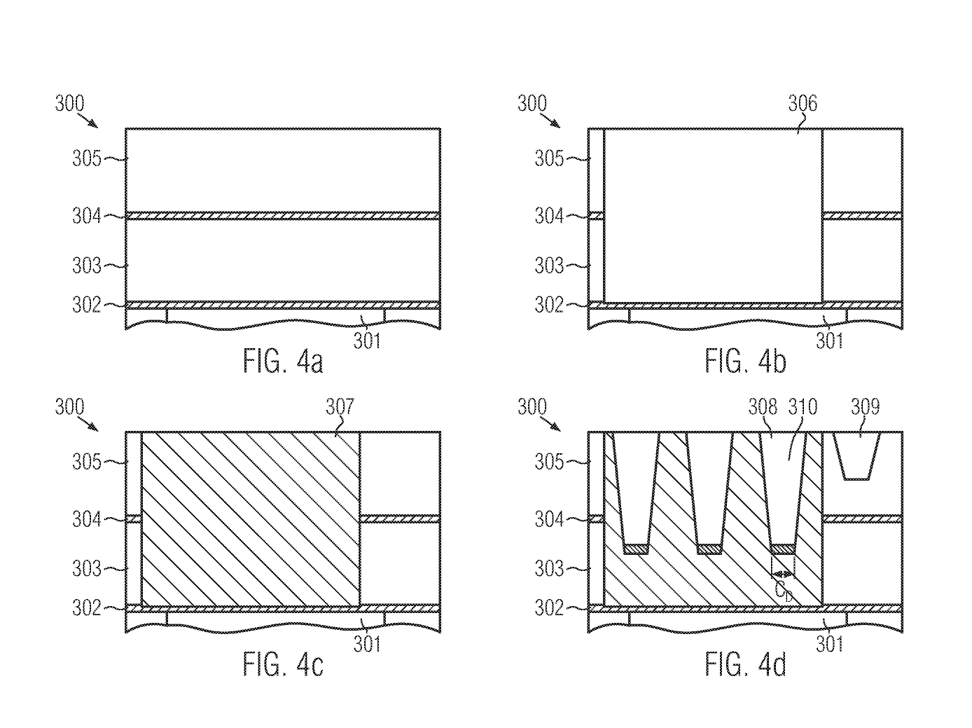

Another exemplary method of forming an inductor will now be described with reference to FIGS. 4a-4d. FIG. 4a shows a semiconductor device 300 comprising a first metallization layer 302 over some conductive structure 301, a first dielectric layer, for example, a first ILD layer, 303 over the first metallization layer 302, a second metallization layer 304 over the first dielectric layer 303 and a second dielectric layer, for example, a second ILD layer, 305 over the second metallization layer 304. A planarization process, for example, a chemical mechanical polishing process, may be performed after the deposition of the second dielectric layer 305 for obtaining a substantially planar surface. A substrate similar to the one described with reference to FIG. 1a might be provided instead of the conductive structure 301 and the first metallization layer 302. A device layer comprising semiconductor devices such as transistor, capacitors and/or resistors, for example, might be provided instead of the second metallization layer 304.

The first and second dielectric layers 303 and 305 may be made of a low-k material. In one example, ILDs including a silicon oxide material and having thicknesses of about 50 nm to about 1 micron, for example a thickness of about 100 nm to about 500 nm, may be provided. According to an example, the ILDs may consist of or comprise an ultralow-k (ULK) material with k of at most 2. The ILDs may be blanket-deposited using, for example, plasma enhanced chemical vapor deposition (PECVD), a low pressure chemical vapor deposition (LPCVD), or a chemical vapor deposition (CVD) process.

However, according to the shown example, parts of the first and second dielectric layer 303 and 305 as well as the second metallization layer 304 are removed (see FIG. 4b). Alternatively, a part of the second dielectric layer 305 only may be removed. Removal of parts of the dielectric layers(s) may be achieved by forming a mask layer on or over the second dielectric layer 305, patterning the mask layer appropriately and etching the parts of the dielectric layer(s) by performing an etching process through a suitably arranged opening of the patterned mask layer. In the opened area 306 an inductor will be formed. In particular, the opened area might be formed by removing the dielectric materials after completion of the regular BEOL processing providing for the wiring of transistors, capacitors, resistors, etc.

The opened area 306 is filled with another dielectric material 307 (FIG. 4c). The choice of this additional dielectric material 307 in a region where an inductor has to be formed may be made in view of the desired conductor characteristics without affecting the overall chip performance. In particular, the additional dielectric material 307 may have mechanical and electrical properties that are different from the ones of the materials of the dielectric layers 303 and 304 and may be optimized for the inductor formation process. The additional dielectric material 307 may be chosen according to the desired etch performance, allowing for reduced critical dimensions (pitches) of trenches filled with some conductive material to be formed for producing a coil inductor.

Moreover, the resistance of the trenches may be adjusted by a proper choice of material of the additional dielectric independent of the normal BEOL processing using the dielectric material of dielectric layers 303 and 305. The additional dielectric material 307 may be chosen such that it allows for a proper deposition of a ferromagnetic material into trenches formed in the additional dielectric material 307 thereby significantly increasing, the performance of the finished inductor. The additional dielectric material 307 may be blanket-deposited using, for example, plasma enhanced chemical vapor deposition (PECVD), a low pressure chemical vapor deposition (LPCVD), or a CVD process. The additional dielectric material 307 may comprise or consist of SiCOH with different porosities, carbon doped or fluorine doped silicon dioxide, (organic) polymers, etc.

FIG. 4d shows the semiconductor device 300 in a further developed manufacturing stage. Trenches 308 are formed in the additional dielectric material 307. For comparison, a “normal” trench 309 formed in the material of the second dielectric layer 305 is also shown in FIG. 4d. The trenches 308 may be formed by means of a patterned hard mask, for example, a nitride mask, in particular, an SiN mask, and they may be formed by etching. The trenches 308 are filled with some conductive material 310, for example copper. As described above, the process of filling the trenches 308 may include depositing a barrier layer and/or depositing a seed layer. According to an example, the trenches 308 are filled with a ferromagnetic material, for example, comprising Ni or Co. The inductor formed according to the example described with reference to FIGS. 4a-4d may have a spiral structure formed by the trenches 308 filled with material 310 similar to the one shown in FIG. 2.

Due to the properties of the additional dielectric material 307, the trenches 308 are formed deeper than “normal” trench 309. In particular, the trenches 308 of the conductor to be formed may extend beyond the second metallization layer 304. Moreover, the critical dimensions (CDs) at the bottom of the trenches 308 are smaller than the CD of the “normal” trench 309. In the context of the 28 nm technology, examples of values of CDs comprise a nominal minimum trench width of about 50 nm and in the context of the 20 nm technology of about 40 nm.

A higher coil density as compared to the art may be achieved by means of the provision of the additional dielectric material 307 wherein the trenches 308 are formed.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is, therefore, evident that the particular embodiments disclosed above may be altered or modified and all such variations are considered within the scope and spirit of the invention. Accordingly, the protection sought herein is as set forth in the claims below.

What is claimed:

1. A method of forming a semiconductor device comprising an inductor, comprising the steps of:
forming a first dielectric layer of a first dielectric material over a substrate;
removing a part of said first dielectric layer to create an opening in said first dielectric layer;
filling said opening with a second dielectric layer of a second dielectric material different from said first dielectric material;
forming a trench in said second dielectric layer; and
filling said trench with a conductive material to form an inductor coil.

2. The method of claim 1, wherein said first dielectric layer is formed on or over a device layer.

3. The method of claim 1, wherein said first dielectric layer is formed on or over a metallization layer or as part of a metallization layer.

4. The method of claim 1, wherein said trench is formed to reach at least to one of a device layer and a metallization layer formed below said first dielectric layer.

5. The method of claim 1, wherein said first dielectric layer is the uppermost dielectric layer of said semiconductor device.

6. The method of claim 1, further comprising Back-End-of-Line processing of said semiconductor device and wherein said part of said first dielectric layer is removed after completion of said Back-End-of-Line processing.

7. The method of claim 1, further comprising forming a trench in said first dielectric material of said first dielectric layer with a critical dimension larger than a critical dimension of said trench formed in said second dielectric material of said second dielectric layer or with a depth smaller than a depth of said trench formed in said second dielectric material of said second dielectric layer.

8. A semiconductor device comprising an inductor, wherein said semiconductor device comprises:
a first dielectric layer made of a first dielectric material;
a second dielectric layer made of a second dielectric material different from said first dielectric material and embedded in said first dielectric layer; and
a trench filled with a conductive material and formed in said second dielectric layer and representing at least a part of an inductor coil of said inductor.

9. The semiconductor device of claim 8, further comprising a device layer and a metallization layer and wherein said first dielectric layer is formed at least one of over said device layer, on said device layer, over said metallization layer, on said metallization layer and in said metallization layer.

10. The semiconductor device of claim 8, further comprising a trench formed in said first dielectric layer with a critical dimension larger than a critical dimension of said trench formed in said second dielectric material of said second dielectric layer or with a depth smaller than a depth of said trench formed in said second dielectric material of said second dielectric layer.

11. A method of forming a semiconductor device comprising an inductor, comprising the steps of:
forming a dielectric layer over or as part of a metallization layer;
performing a two-step etching process of said dielectric layer comprising:
performing a first etching step to form a first trench with a first depth in said dielectric layer;
performing a second etching step to form a second trench with a second depth in said dielectric layer and to further etch said first trench to increase said first depth of said first trench to a third depth deeper than said second depth; and
filling said first trench with said third depth with a conductive material to form an inductor coil.

12. The method of claim 11, wherein said third depth reaches to a metallization layer or device layer formed below said dielectric layer.

13. The method of claim 11, further comprising:
forming a first mask layer over said dielectric layer;
forming a second mask layer over said first mask layer;
forming a first opening in said second mask layer to expose a first part of said first mask layer;
removing said exposed first part of said first mask layer;
wherein said first etching step is performed through said first opening of said second mask layer;
forming a second opening in said second mask layer to expose a second part of said first mask layer;
removing said exposed second part of said first mask layer; and
wherein said second etching step is performed through said first and second openings of said second mask layer.

14. The method of claim 11, further comprising:
forming a mask layer over said dielectric layer;
forming a first opening in said mask layer;
wherein said first etching step is performed through said first opening of said mask layer;
forming a second opening in said mask layer; and
wherein said second etching step is performed through said first and second openings of said mask layer.

15. The method of claim 11, further comprising forming an additional dielectric layer over or below said dielectric layer and forming parts of said inductor coil in said additional dielectric layer.

16. The method according to claim 15, wherein forming parts of said inductor coil in said additional dielectric layer comprises:
performing an additional two-step etching process of said additional dielectric layer comprising:
performing a third etching step to form a third trench with a fourth depth in said additional dielectric layer;
performing a fourth etching step to form a fourth trench with a fifth depth in said additional dielectric layer and to further etch said third trench to increase said fourth depth of said third trench to a sixth depth deeper than said fifth depth; and
filling said third trench with said sixth depth with a conductive material to form said inductor coil.
